(19) United States
(12) Patent Application Publication
(10) Pub. No.: US 2017/0229800 A1
(43) Pub. Date: Aug. 10, 2017

(54) MIDPLANE COMMUNICATION SYSTEM

(71) Applicant: ELECTRONICS AND TELECOMMUNICATIONS RESEARCH INSTITUTE, Daejeon (KR)

(72) Inventors: Chang Ho CHOI, Daejeon (KR); Tae Sik CHEUNG, Daejeon (KR); Woo Young CHOI, Daejeon (KR)

(21) Appl. No.: 15/236,756

(22) Filed: Aug. 15, 2016

(30) Foreign Application Priority Data
Feb. 5, 2016 (KR) 10-2016-0015192

(51) Int. Cl. H01R 12/73; H05K 7/14

(52) U.S. Cl. CPC H01R 12/737; H05K 7/1445

(57) ABSTRACT

A midplane communication system includes: a midplane; at least one front daughter card configured to connect to a front side of the midplane; at least one rear daughter card configured to connect to a rear side of the midplane in a vertical direction relative to the front daughter card; and an orthogonal connector configured to electrically connect the front daughter card and the rear daughter card, wherein the orthogonal connector is configured to connect to the midplane at a vertical or horizontal offset to include at least one extra connection pin allowing an additional connection when connecting the front daughter card and the rear daughter card.

### CROSS-REFERENCE TO RELATED APPLICATION(S)

This application claims the priority benefit of Korean Patent Application No. 10-2016-0015192, filed on Feb. 5, 2016, in the Korean Intellectual Property Office, the disclosure of which is incorporated herein by reference for all purposes.

### BACKGROUND

1. Field

One or more example embodiments relate to a structure of a midplane communication system.

2. Description of Related Art

A midplane using an orthogonal connector includes two corresponding connectors positioned on a front side and a rear side, respectively. To minimize and simplify a length of a signal routed on the midplane, two orthogonal connectors may be connected through a via formed on a midplane printed circuit board (PCB).

An orthogonal connector according to a related art is provided in a structure in which two connectors having the same number of electrical connection points are disposed to face each other based on a midplane and all of the electrical connection points are connected through vias formed on a midplane PCB. Accordingly, a signal line for electrical connection with another connector excluding two corresponding connectors may not be routed on the midplane PCB. To outperform the above issues, an exclusive connector for connection between neighboring daughter cards may be used separate from an orthogonal connector. However, it may significantly limiting a use of a space of a midplane, which may result in reducing the capacity of a communication system.

### SUMMARY

At least one example embodiment provides a midplane structure that may facilitate a design of a midplane structure and may maximize the capacity of a communication system by effectively disposing corresponding orthogonal connectors instead of using an additional connector that includes a cable connection, when embodying an electrical signal connection between neighboring daughter cards on a midplane printed circuit board (PCB) in a midplane structure using an orthogonal connector.

According to an aspect of at least one example embodiment, there is provided a midplane communication system including a midplane; at least one front daughter card configured to connect to a front side of the midplane; at least one rear daughter card configured to connect to a rear side of the midplane in a vertical direction relative to the front daughter card; and an orthogonal connector configured to electrically connect the front daughter card and the rear daughter card. The orthogonal connector is configured to connect to the midplane vertical or horizontal offset to include at least one extra connection pin allowing an additional connection when connecting the front daughter card and the rear daughter card.

The orthogonal connector may include a front orthogonal connector configured to connect to the front daughter card; and a rear orthogonal connector configured to connect to the rear daughter card corresponding to the front daughter card.

The front orthogonal connector and the rear orthogonal connector may be configured to be connected through a via of the midplane.

The extra connection pin of the front orthogonal connector may be used to electrically connect a first front daughter card and a second front daughter card among a plurality of front daughter cards.

The extra connection pin of the rear orthogonal connector may be used to electrically connect a first rear daughter card and a second rear daughter card among one or more rear daughter cards.

A number of extra connection pins of the front orthogonal connector and the rear orthogonal connector may be determined based on a number of connection pins used to connect the front orthogonal connector and the rear orthogonal connector.

The front orthogonal connector and the rear orthogonal connector may be configured to connect at a vertical or horizontal offset to secure the extra connection pin.

According to another aspect of at least one example embodiment, there is provided a midplane printed circuit board (PCB) including a plurality of front connectors disposed on a front side of a midplane; and a plurality of rear connectors disposed on a rear side of the midplane to be vertical relative to the plurality of front connectors. The plurality of front connectors and the plurality of rear connectors are disposed based on a preset vertical or horizontal offset, and a portion of pins included in the front connectors and a portion of pins included in the rear connectors are disposed to overlap, and an extra pin is formed on each of the front connector and the rear connector.

A portion of pins included in the front connector and a portion of pins included in the rear connector may be connected through vias, extra pins included in the front connector may be connected through first connection pins, and extra pins included in the rear connector may be connected through second connection pins.

According to some example embodiments, there is provided a midplane structure that may facilitate a design of a midplane structure and may maximize the capacity of a communication system by effectively disposing corresponding orthogonal connectors instead of using an additional connector that includes a cable connection when embodying an electrical signal connection between neighboring daughter cards on a midplane PCB in a midplane structure using an orthogonal connector.

According to some example embodiments, there is provided a midplane communication system using an orthogonal connector that may provide electrical connection between connectors disposed on a front side and a rear side by employing only a general orthogonal connector, and may also provide a connection pin of a neighboring connector from the same connector.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a perspective view illustrating a communication system in a midplane structure using an orthogonal connector according to at least one example embodiment;

FIG. 2A is a view illustrating orthogonal connectors vertically disposed on a front side of a midplane according to at least one example embodiment;

FIG. 2B is a view illustrating orthogonal connectors horizontally disposed on a rear side of a midplane according to at least one example embodiment;

FIG. 3A is a view illustrating orthogonal connectors vertically disposed on a front side of a midplane including an additional connector according to at least one example embodiment;

FIG. 3B is a view illustrating orthogonal connectors horizontally disposed on a rear side of a midplane including an additional connector according to at least one example embodiment;

FIG. 4 is a perspective view to describe a method of vertically and horizontally connecting orthogonal connectors according to at least one example embodiment; and

FIG. 5 is a view illustrating a structure of a midplane using an orthogonal connector according to at least one example embodiment.

### DETAILED DESCRIPTION

Hereinafter, some example embodiments will be described in detail with reference to the accompanying drawings.

The following example embodiments may be variously modified and are provided as examples only and are not to be construed as being limited. Thus, various changes, modifications, and equivalents of the example embodiments described herein will be apparent to one of ordinary skill in the art.

The terminology used herein is for the purpose of describing particular example embodiments only, and is not to be used to limit the example embodiments. As used herein, the terms “a”, “an”, and “the” are intended to include the plural forms as well, unless context clearly indicates otherwise. As used herein, the terms “include”, “comprise”, and “have” specify the presence of stated features, numbers, operations, elements, components, and/or combinations thereof, but do not preclude the presence or addition of one or more other features, numbers, operations, elements, components, and/or combinations thereof.

Unless otherwise defined, all terms including technical and scientific terms used herein have the same meaning as commonly understood by one of ordinary skill in the art to which this disclosure pertains. Terms, such as those defined in commonly used dictionaries, are to be interpreted as having a meaning that is consistent with their meaning in the context of the relevant art, and are not to be interpreted in an idealized or overly formal sense unless expressly so defined herein.

When describing the example embodiments with reference to the accompanying drawings, like reference numerals refer to like constituent elements and repeated description related thereto will be omitted. When it is determined discussions related to a related known operation or configuration that may make the purpose of the example embodiments unnecessarily ambiguous in describing the example embodiments, such discussions in the detailed description will be omitted here.

The example embodiments relate to technology for providing an efficient electrical signal connectivity between connectors in a communication system using a midplane structure, and more particularly, to a method of providing an electrical signal connection between neighboring daughter cards by employing only an orthogonal connector in a midplane using corresponding orthogonal connectors.

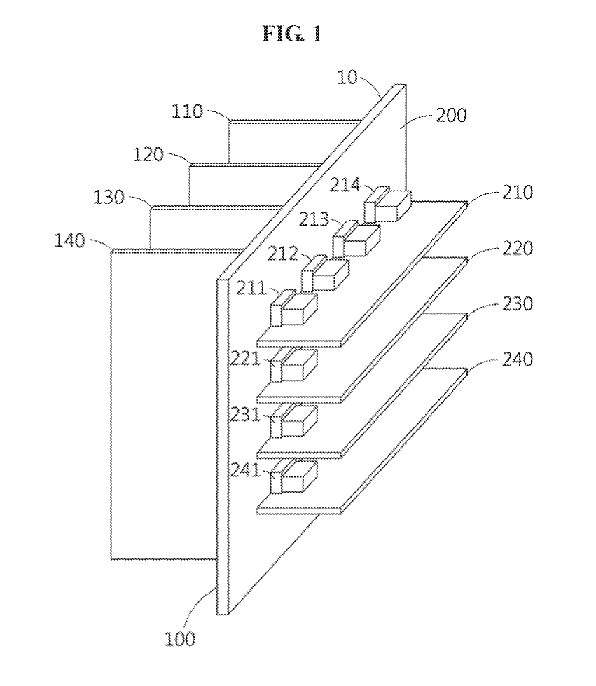

FIG. 1 is a perspective view illustrating a communication system in a midplane structure using an orthogonal connector according to at least one example embodiment.

Referring to FIG. 1, a midplane 10 may include a front side 100 and a rear side 200 to which daughter cards 110, 120, 130, 140, 210, 220, 230, and 240 are disposed.

The daughter cards 110, 120, 130, and 140 disposed on the front side 100 of the midplane 10 may be electrically connected to the daughter cards 210, 220, 230, and 240 disposed on the rear side 200 through orthogonal connectors (not shown) disposed on the front side 100. The daughter cards 210, 220, 230, and 240 disposed on the rear side 200 may be electrically connected to the daughter cards 110, 120, 130, and 140 disposed on the front side 100 through orthogonal connectors disposed on the rear 200, and may mutually exchange electrical signals.

In FIG. 1, the daughter cards 110, 120, 130, and 140 disposed on the front side 100 and the daughter cards 210, 220, 230, and 240 disposed on the rear side 200 may be disposed to be vertical with respect to each other based on the midplane 10.

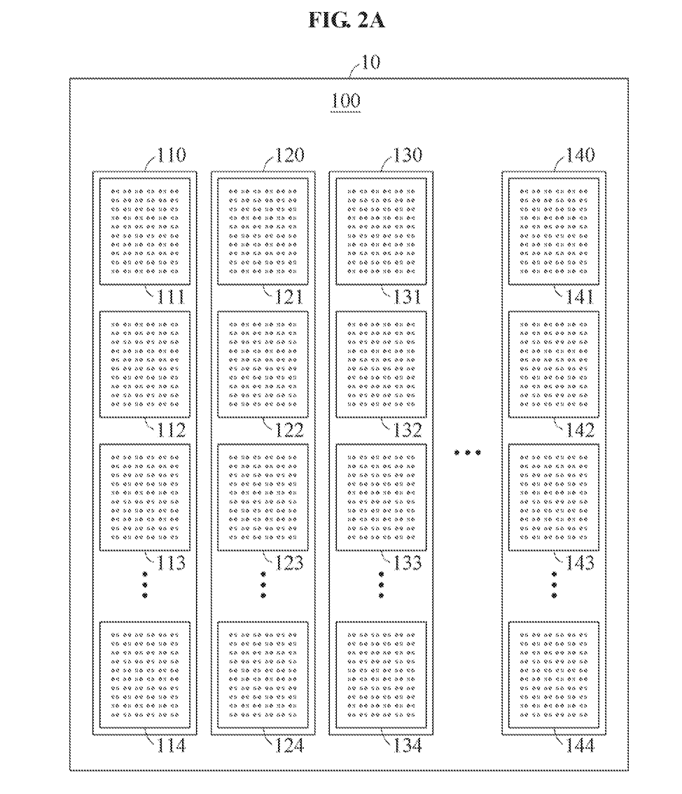

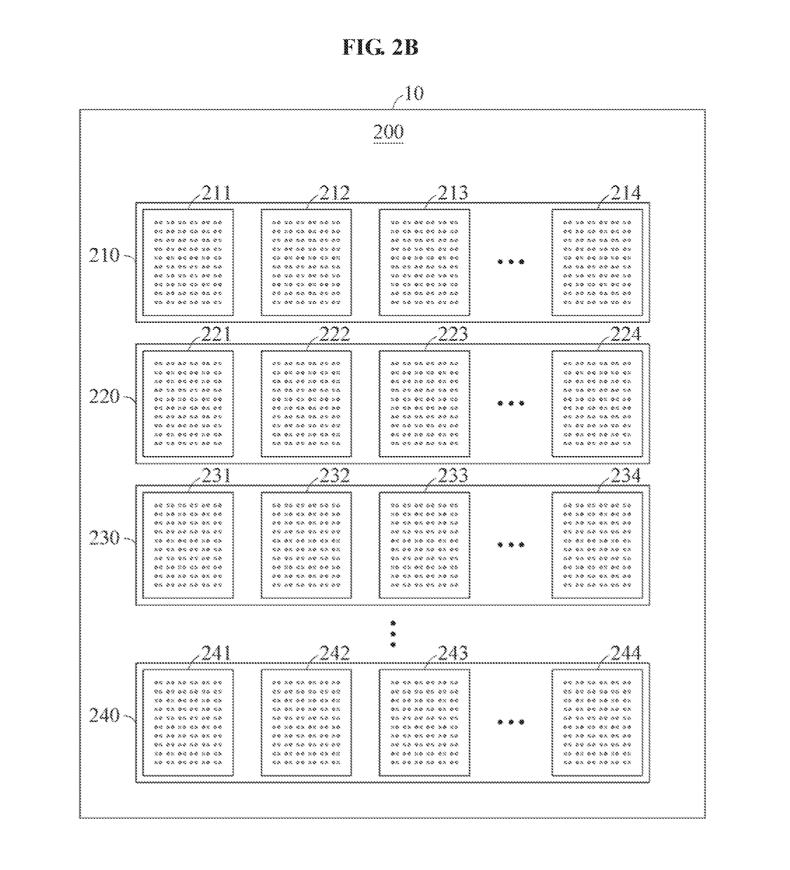

FIGS. 2A and 2B illustrate orthogonal connectors disposed in a vertical direction of a front side and a horizontal direction of a rear side of a midplane according to at least one example embodiment.

In detail, FIG. 2A is a view illustrating orthogonal connectors used for connecting daughter cards to the front side 100 of the midplane 10 according to at least one example embodiment, and FIG. 2B is a view illustrating orthogonal connectors used for connecting daughter cards to the rear side 200 of the midplane 10 according to at least one example embodiment. Referring to FIGS. 2A and 2B, a daughter card connected to the front side 100 (hereinafter, a front daughter card) and a daughter card connected to the rear side 200 (hereinafter, a rear daughter card) may be vertically disposed.

Referring to FIG. 2A, the front daughter cards 110, 120, 130, and 140 may be disposed on the front side 100 of the midplane 10 through the respective corresponding orthogonal connectors (also, referred to as front orthogonal connectors) 111 to 114, 121 to 124, 131 to 134, and 141 to 144. In an example embodiment, the daughter cards 110, 120, 130, and 140 may use independent orthogonal connectors for electrical connection with the rear daughter cards 210, 220, 230, and 240 disposed on the rear side 200, respectively.

For example, a first front orthogonal connector 111 of the first daughter card 110 disposed on the leftmost side of the front side 100 may be used for electrical connection with the rear daughter card 210 disposed in a first horizontal direction on the rear side 200, and a second front orthogonal connector 112 of the first daughter card 110 may be used for electrical connection with the rear daughter card 220 disposed in a second horizontal direction on the rear side 200.

The similar method may be applied to electrically connect the other orthogonal connectors 113, 114, 131 to 134, and 141 to 144 to the rear daughter cards 210, 220, 230, and 240.

Referring to FIG. 2B, the rear daughter cards 210, 220, 230, and 240 may be disposed on the rear side 200 of the midplane 10 through the respective corresponding orthogonal connectors (also, referred to as rear orthogonal connectors) 211 to 214, 221 to 224, 231 to 234, and 241 to 244. In an example embodiment, the rear daughter cards 210, 220, 230, and 240 may use independent orthogonal connectors for electrical connection with the front daughter cards 110, 120, 130, 140 disposed on the front side 100, respectively.

Referring to FIGS. 2A and 2B, the front daughter cards 110, 120, 130, and 140 disposed on the front side 100, and the rear daughter cards 210, 220, 230, and 240 disposed on the rear side 200 based on the midplane 10 may be electrically connected through the orthogonal connectors. In contrast, electrical connection between the front daughter cards 110, 120, 130, and 140 disposed on the front side 100 and/or electrical connection between the rear daughter cards 210, 220, 230, and 240 disposed on the rear side 200 may be difficult.

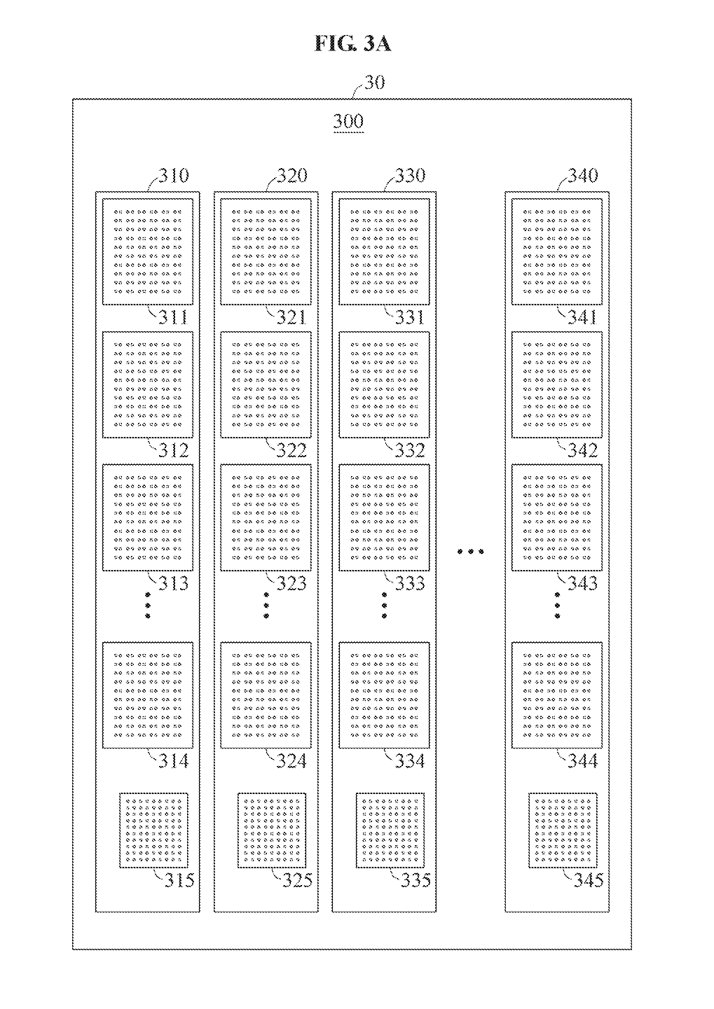

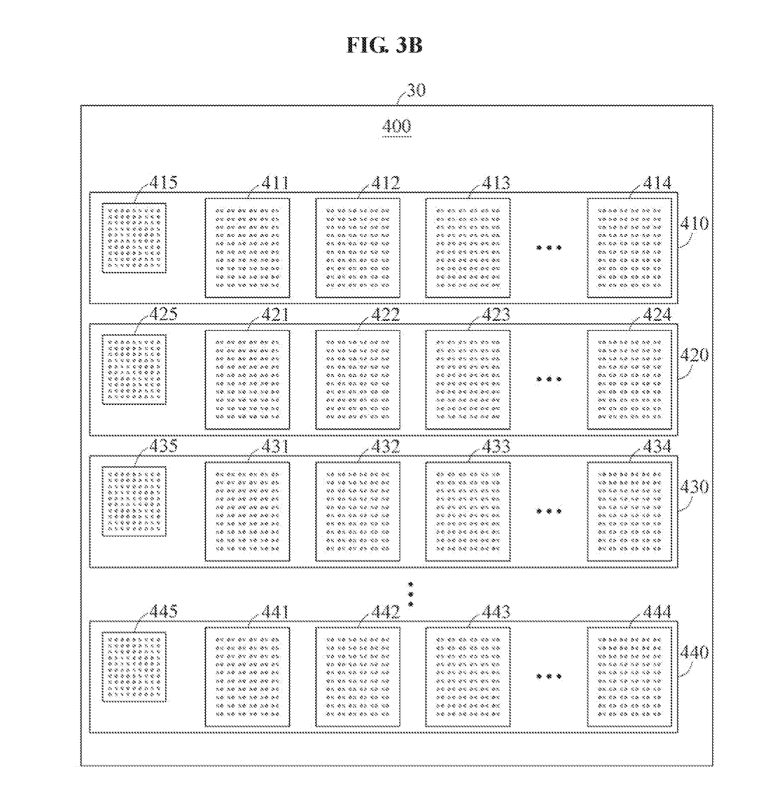

FIGS. 3A and 3B illustrate orthogonal connectors disposed in a vertical direction of a front side and a horizontal direction of a rear side of a midplane including an additional connector according to at least one example embodiment.

In detail, FIG. 3A is a view illustrating orthogonal connectors vertically disposed on a front side 300 of a midplane 30 according to at least one example embodiment, and FIG. 3B is a view illustrating orthogonal connectors horizontally disposed on a rear side 400 of the midplane 30 to be vertical relative to the front side 300 according to at least one example embodiment.

Referring to FIG. 3A, connectors 315, 325, 335, and 345 may be added for electrical connection between front daughter cards 310, 320, 330, and 340 disposed on the front side 300. Orthogonal connectors 311 to 314, 321 to 324, 331 to 334, and 341 to 344 may require corresponding orthogonal connector 411 to 414, 421 to 424, 431 to 434, and 441 to 444 on the rear side 400, whereas the connectors 315, 325, 335, and 345 may not require corresponding connectors on the rear side 400.

Referring to FIG. 3B, connectors 415, 425, 435, and 445 may be added for electrical connection between rear daughter cards 410, 420, 430, and 440 disposed on the rear side 400. Orthogonal connectors 411 to 414, 421 to 424, 431 to 434, and 441 to 444 may require corresponding orthogonal connectors 311 to 314, 321 to 324, 331 to 334, and 341 to 344 on the front side 300, whereas the connectors 415, 425, 435, and 445 may not require corresponding connectors on the front side 300, which is similar to the example of FIG. 3A.

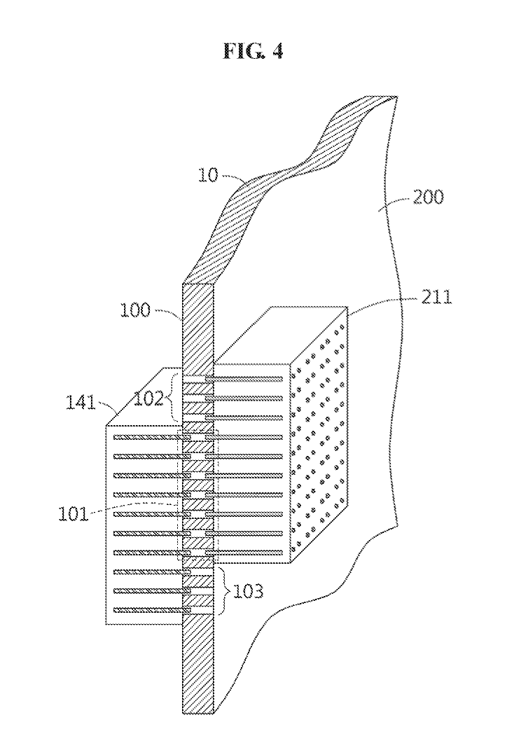

FIG. 4 is a perspective view to describe a method of vertically and horizontally connecting orthogonal connectors according to at least one example embodiment.

Referring to FIG. 4, a front orthogonal connector 141 is disposed on the front side 100 and a rear orthogonal connector 211 corresponding to the front orthogonal connector 141 is disposed on the rear side 200 based on the midplane 10.

For example, the front orthogonal connector 141 disposed on the front side 100 may correspond to the first front orthogonal connector 141 of the first front daughter card 140 disposed on the rightmost side of the front side 100 of FIG. 2A, and the rear orthogonal connector 211 disposed on the rear side 200 may correspond to the first rear orthogonal connector 211 of the first rear daughter card 210 disposed on an uppermost side of the rear side 200 of FIG. 2B. Alternatively, the front orthogonal connector 141 and the rear orthogonal connector 211 may be regarded as a front orthogonal connector disposed at another location and a rear orthogonal connector disposed at a location corresponding to the front orthogonal connector, respectively.

The front orthogonal connector 141 and the rear orthogonal connector 211 may maintain a mutual electrical connection state through vias 101 formed on the midplane 10. Also, when disposing the front orthogonal connector 141 and the rear orthogonal connector 211, a plurality of connection pins 102 and 103 that may be routed on a midplane PCB through a vertical or horizontal offset, for example, deviation, may be secured. Electrical connection between front daughter cards and electrical connection between rear daughter cards are enabled using the connection pins 102 and 103.

In an example embodiment, if necessary, a number of vias 101 for connection between the front orthogonal connector 141 and the rear orthogonal connector 211, a number of connection pins 103 for connection between the front daughter cards, and a number of connection pins 102 for connection between the rear daughter cards may be modified by adjusting a vertical or horizontal offset.

The remaining connection pin(s) 103 unused for electrical connection with the rear orthogonal connector 211 disposed on the rear side 200, among the connection pins of the front orthogonal connector 141 disposed on the front side 100, may be used for electrical connection with other front daughter cards 110, 120, and 130 of FIG. 2A disposed on the front side 100.

In the same manner, the remaining connection pin(s) 102 unused for electrical connection with the front orthogonal connector 141 disposed on the front side 100, among connection pins of the rear orthogonal connector 211 disposed on the rear side 200, may be used for electrical connection with other rear daughter cards 220, 230, and 240 of FIG. 2B disposed on the rear side 200.

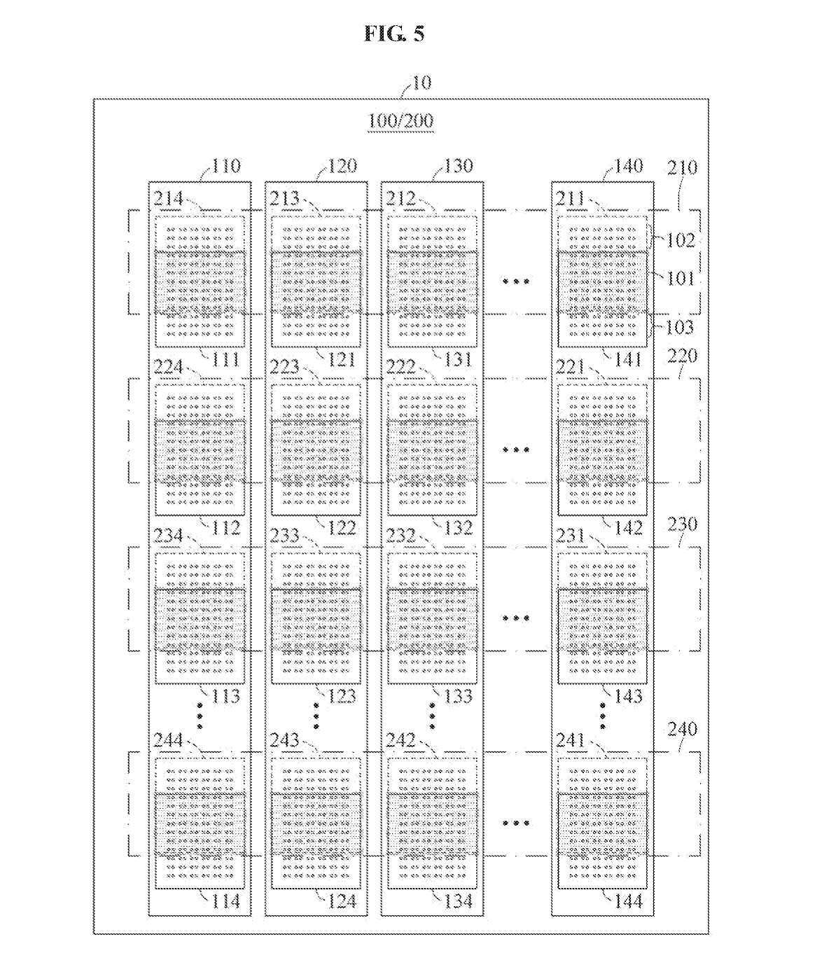

FIG. 5 is a view illustrating a structure of a midplane using an orthogonal connector according to at least one example embodiment.

Referring to FIG. 5, front daughter cards 110, 120, 130, and 140 vertically disposed on the front side 100 of the midplane 10, indicated with solid lines, and rear daughter cards 210, 220, 230, and 240 horizontally disposed on the rear side 200, indicated with dotted lines, may be electrically connected using the respective corresponding front orthogonal connectors 111 to 114, 131 to 134, and 141 to 144 and rear orthogonal connectors 211 to 214, 221 to 224, 231 to 234, and 241 to 244.

In an example embodiment, the rear daughter cards 210, 220, 230, and 240 and the rear orthogonal connectors 211 to 214, 221 to 224, 231 to 234, and 241 to 244 disposed on the rear side 200 are illustrated to pass through the midplane 10 and be projected as indicated with dotted lines in view observed from the front side 100.

In an example embodiment, the front orthogonal connectors 111 to 114, 131 to 134, and 141 to 144 disposed on the front side 100 and the rear orthogonal connector 211 to 214, 221 to 224, 231 to 234, and 241 to 244 disposed on the rear side 200 are disposed using a vertical offset of three lines, for example, three connection pins. However, if necessary, a vertical offset may be changed with a horizontal offset. A number of offsets may be changed.

For example, describing by representatively using the first front orthogonal connector 141 of the first front daughter card 140 disposed on the rightmost side of the front side 100 and the first rear orthogonal connector 211 of the first rear daughter card 210 disposed on the uppermost side of the rear side 200, the front orthogonal connector 141 disposed on the front side 100 and the rear orthogonal connector 211 disposed on the rear side 200 may be electrically connected through a via of the midplane 10. A shaded portion of FIG. 5 may correspond to a substantial connection portion.

Connection pins 103 in a three-line form may be allocated at a lower end of the front orthogonal connector 141 for electrical connection between the neighboring front daughter cards 110, 120, and 130. Connection pins 102 in a three-line form may be allocated at an upper end of the rear orthogonal connector 211 for electrical connection between the neighboring rear daughter cards 220, 230, and 240.

The connection pin 102, 103 allocated for connection with a neighboring daughter card at each of the orthogonal connectors 111 to 114, 121 to 124, 131 to 134, 141 to 144, 211 to 214, 221 to 224, 231 to 234, 241 to 244 may be electrically connected with another orthogonal connector through electrical routing on a midplane PCB.

According to some example embodiments, there is provided a midplane structure that may facilitate a design of a midplane structure and may maximize the capacity of a communication system by effectively disposing corresponding orthogonal connectors instead of using an additional connector that includes a cable connection when embodying an electrical signal connection between neighboring daughter cards on a midplane PCB in a midplane structure using an orthogonal connector.

According to some example embodiments, there is provided a midplane communication system using an orthogonal connector that may provide electrical connection between connectors disposed on a front side and a rear side by employing only a general orthogonal connector, and may also provide a connection pin of a neighboring connector from the same connector.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

1. A midplane communication system comprising:
a midplane;
at least one front daughter card configured to connect to a front side of the midplane;
at least one rear daughter card configured to connect to a rear side of the midplane in a horizontal direction relative to the at least one front daughter card which is configured to connect to the front side of the midplane in a vertical direction relative to the at least one rear daughter card; and
an orthogonal connector configured to electrically connect the front daughter card and the rear daughter card,
wherein the orthogonal connector is configured to connect to the midplane at a vertical or horizontal offset to include at least one extra connection pin allowing an additional electrical connection to be made between two or more of the at least one front daughter card and/or between two or more of the at least one rear daughter card when connecting the at least one front daughter card and the at least one rear daughter card to each other.

2. The midplane communication system of claim 1, wherein the orthogonal connector comprises:
a front orthogonal connector configured to connect to the front daughter card; and
a rear orthogonal connector configured to connect to the rear daughter card corresponding to the front daughter card.

3. The midplane communication system of claim 2, wherein the front orthogonal connector and the rear orthogonal connector are configured to be connected through a via of the midplane.

4. The midplane communication system of claim 2, wherein the extra connection pin of the front orthogonal connector is used to electrically connect a first front daughter card and a second front daughter card among a plurality of front daughter cards to each other.

5. The midplane communication system of claim 2, wherein the extra connection pin of the rear orthogonal connector is used to electrically connect to each other a first rear daughter card and a second rear daughter card among one or more rear daughter cards.

6. The midplane communication system of claim 2, wherein a number of extra connection pins of the front orthogonal connector and the rear orthogonal connector is determined based on a number of connection pins used to connect the front orthogonal connector and the rear orthogonal connector.

7. The midplane communication system of claim 2, wherein a size of the front orthogonal connector is same as a size of the rear orthogonal connector.

8. A midplane printed circuit board (PCB) comprising:
a plurality of first connectors disposed on a first side of the midplane PCB in a vertical direction; and
a plurality of second connectors disposed on a second side of the midplane PCB to be horizontal relative to the plurality of first connectors,
wherein the plurality of first connectors and the plurality of second connectors are disposed relative to each other based on a preset vertical or horizontal offset, and
a plurality of overlapping first pins included in one or more first connectors of the plurality of first connectors and a plurality of overlapping second pins included in one or more second connectors of the plurality of second connectors are disposed to overlap the one or more overlapping first pins, and each of the one or more first connectors includes one or more extra first pins and each of the one or more second connectors includes one or more extra second pins.

9. The midplane PCB of claim 8, wherein each of the plurality of overlapping first pins and is connected to a corresponding overlapping second pin of the plurality of overlapping second pins through vias,
the one or more extra first pins included in the one or more first connectors connect the one or more first connectors to each other, and
the one or more extra second pins included in the one or more second connectors connect the one or more second connectors to each other.

10. The midplane PCB of claim 8, wherein the first side of the midplane PCB is a front side of the midplane PCB and the second side of the midplane PCB is a rear side of the midplane PCB.
